(19) United States
(12) Patent Application Publication
(10) Pub. No.: US 2007/0012402 A1
(43) Pub. Date: Jan. 18, 2007

(54) Apparatus and method for downstream pressure control and sub-atmospheric reactive gas abatement

(75) Inventor: Ofer Sneh, Boulder, CO (US)

Correspondence Address: PATTON BOGGS, 1660 LINCOLN ST, SUITE 2050, DENVER, CO, 80264, US

(73) Assignee: Sundew Technologies, LLC, Broomfield, CO (US)

(21) Appl. No.: 10/563,519

(22) PCT Filed: Jul. 8, 2004
(86) PCT No.: PCT/US04/22182

§ 371 Date: Jun. 20, 2006

Related U.S. Application Data
(60) Provisional application No. 60/485,547, filed on Jul. 8, 2003.

(51) Int. Cl. F17D 1/16; H01L 21/306

(52) U.S. Cl. 156/345.29; 156/345.26; 137/14

(57) ABSTRACT

A sub-atmospheric downstream pressure control apparatus (200) includes a first flow restricting element (FRE) (202); a pressure control chamber (PCC) (204) located in serial fluidic communication downstream from the first FRE; a second FRE (206) located in serial fluidic communication downstream from the PCC; a gas source (208); and a flow controlling device (210) in serial fluidic communication downstream from the gas source and upstream from the PCC.

### BACKGROUND OF THE INVENTION

1. Field of the Invention

This invention relates to the area of substrate processing and more specifically to apparatus and method for controlling pressure during deposition or etching processes and for effectively removing reactive chemicals from exhaust gas streams.

2. Description of Prior Art

Low-pressure process systems are implemented extensively for semiconductor processing such as chemical vapor deposition (CVD) and etch. Typically these systems must employ both upstream effluent flow control and downstream pressure control to achieve satisfactory results. The technology of upstream effluent flow control is satisfactory and historically has never been a performance or cost bottleneck. However, downstream pressure control and foreline effluent management continue to be maintenance intensive and performance-limiting bottlenecks. Upstream manifolds need only to handle pure gasses within small diameter lines and relatively high pressure. Accordingly, possible deterioration of upstream lines due to deposition and corrosion from reactive chemicals are rarely an issue and are much easier to handle when delivery lines and elements are small and compact.

In contrast, effluents going through downstream manifolds typically include reactive mixtures or unstable byproducts and reactants that can deposit solid material and/or extensively corrode the downstream flow-lines. Low-pressure delivery dictates large diameter conduits (forelines) to provide adequate conductance at typically low pressures. Downstream pressure-control is conventionally implemented with a mechanical throttle valve device. Throttle valves are inserted into the downstream manifold and provide downstream pressure control with feedback “corrective act” response to fluctuations of chamber pressure. Corrective act refers to the operation that the control device has to apply to restore the controlled property, i.e. the process pressure, to the set point. Pressure control with a throttle-valve is implemented by partially blocking the flow path of a downstream conduit. Throttle valves typically implement a “butterfly” (also known as “flapper”) type design. In this design a typically round disk is driven to partially block the flow path within a typically round conduit, as depicted in FIG. 1. Other implementations of throttle valves also follow similar method of mechanically altering the conductance of a flow conduit.

Downstream pressure control is necessary to compensate for instabilities of outgoing effluent that could originate from fluctuations in reaction rates, fluctuations in the rate of gaseous byproduct generation, chamber temperature instabilities (for example, affecting the conductance of the foreline) etc. Unfortunately, the mechanical throttle valve is prone for deteriorated performance under most common usage due to the growth of solid deposits on mechanical moving parts. These deposits can clog the valve or impede the mechanical motion that is necessary for adequate performance. In addition, the mechanical motion breaks-off deposits and is prone to make particles that are detrimental to process yield. Throttle valves produce flow turbulences that sometimes affect the process adversely and are further notorious for dislodging particles from the throttle valve vicinity. In addition, the response of throttle valves to pressure fluctuations is often too slow and tends to develop oscillatory response that impact process results disadvantageously. Oscillatory response is driven by the slow response of the mechanical device to pressure changes, in particular during the beginning and end of the process when vast pressure changes are inevitable. The outcomes of throttle valve oscillatory response are disadvantageous process pressure fluctuations and back-flow from the throttle valve area carrying dislodged particles into the process space.

In FIG. 1a a prior art embodiment for downstream pressure control is schematically illustrated in a side cross-sectional view. In FIG. 1b a top cross-sectional view through throttle valve 100 is illustrated for better clarity. Process chamber 10 is fed with process gas 12 through a suitable upstream manifold. Typically, a substrate supporting chuck 18 is positioned inside chamber 14 to support and control the temperature of substrate 20. Process pressure is controlled within space 16 by means of throttle valve 100. The exhaust effluent gas 108 enters throttle valve 100 through inlet 104 and exits through outlet 106 into downstream manifold 110. Downstream manifold can include a high vacuum pump (not shown) and a foreline as is practiced in the art. Throttle valve 100 includes conduit 102 where a rotating disc 112 is mounted on rotation axis 114. The rotation of disc 112 controls the conductance of lower flow path 116 and upper flow path 118 to effectively maintain the desired pressure within processing space 16.

Downstream pressure control without a throttle valve was attempted by flowing inert gas (ballast) into the inlet of vacuum pumps. In particular an embodiment is described in U.S. Pat. No. 5,758,680 and U.S. Pat. No. 6,142,163 for the utilization of pump ballast to effectively downgrade the pumping speed of a turbomolecular pump as a mean of downstream pressure control. The flow of this inert gas was controlled to maintain the pressure in a process chamber. Several deposition equipment manufacturers implemented this technique, mostly in conjunction with a pre-positioned throttle valve. However, pressure control performance was inferior to the throttle valve method. In particular, time response of gas ballast technique was inadequately slow. The invention disclosed in U.S. Pat. No. 5,758,680 and No. 6,142,163 described 2 modes of ballast gas insertion. In the first mode the ballast gas was inserted “as further downstream as possible” but upstream to the location of the throttle valve. In essence, this method was not different than the conventional method of upstream pressure control as is known in the art. In an upstream pressure control method the pressure in the chamber was controlled by controlling the flow of one of the process gas components to maintain the pressure. A disadvantageous and inevitable composition change of inflow gas mixture renders this technique inadequate for most CVD and etch processes and for the majority of reactive sputtering processes. As upstream controlled pressure was deemed inadequate for CVD and etch processes in the prior art, it is not surprising that the method of injecting “ballast” gas upstream to the throttle valve did not produce an improvement to prior art.

In the second case described in the invention disclosed in U.S. Pat. No. 5,758,680 and No. 6,142,163 the flow of ballast gas was directed into the turbomolecular pump inlet and downstream from the throttle valve. In some cases the flow of ballast gas was taught to be directed even further downstream. For example, the ballast gas was recommended to be injected into a lower stage of a turbomolecular pump. However, this method did not produce an improved method for downstream pressure control. A close look at the method of injecting ballast gas downstream from a throttle and into the inlet of a turbomolecular pump reveals that the method is based on controlling the pumping speed of the pump by forcing the pump into a disadvantageous high-load regime where the pumping speed strongly depends on the inflow (pump “choking” mode). Turbomolecular pumps maintain a relatively flow independent pumping speed in the low pressure range and up to a pressure of 5-10 mTorr at the high pressure end. Accordingly, a maximum pressure of 10 mTorr at the pump inlet does not provide a substantial impact on the flow through a throttle valve during typical low pressure CVD (LPCVD) and etch processes. For example, LPCVD processes are rarely run under 100 mTorr of process pressure. The flow throughput through the throttle depends on the square of the pressure differential between the inlet and outlet of the throttle (the term throttle is used here to represent a controllable throttle such as a throttle valve or a fixed conductance conduit). If the pressure at the turbo pump can only be controlled from ˜0 to 10 mTorr the control over flow represents a dismal 1% range of control in the range of flow independent pumping speed. Etch processes with lower process pressure in the 50 mTorr range allow a slightly extended 4% range of control in the range of flow independent pumping speed which is also inadequately small. Accordingly, the pump ballast technique is forced into the range of strongly inflow dependent pumping speed. In this range the pump behaves disadvantageously with characteristics such as slow and oscillating response to changes, substantial sensitivity to the type of gas, fatigue and extended wear.

In a recent effort, pump manufacturers have attempted with partial success to control pressure by varying the pumping speed of a downstream pump. Most implementations of this idea produced unsatisfactory results. Recent report within the invention described in U.S. Pat. No. 6,316,045 has indicated that sophisticated control schemes may be applied to make this idea feasible. However, while it is proven that pumping speed control can serve as a mean to optimize downstream pressure control (performed by any given technique) by setting optimum working pressure point and range for controlling desired process pressure, it is not seen as a possible universal method for throttle valve free downstream pressure-control. In particular, pumping speed control is not adequate for fast response in the sub-second time-scale.

A downstream pressure control apparatus and method free of disadvantageous mechanical motion is needed. Furthermore, a fast-responding downstream pressure control apparatus and method with sub-second time response is needed. Finally, it is also necessary to provide these performance features while maintaining the pumps at their inflow independent pumping speed regime.

Process exhaust effluent may include chemical substances that can deposit solids in the forelines and pumps. These can be solid condensation products, solid films and typically both. These deposits can clog the forelines, flake to make particulates and destroy foreline components such as valves, gauges, sensors and pumps. Most condensed or partially reacted deposits pose also safety hazards upon maintenance. For example, tetraethoxysilane (TEOS) that is used extensively for SiO₂ deposition generates toxic and flammable polymer products mixed with silicone dioxide powder in the foreline. In another example aluminum etch processes produce large quantities of AlCl₃, a pyrophoric solid that can ignite in the ambient and produce toxic HCl fumes. In another example WF₆ and SiH₄ reactants that are not consumed by tungsten CVD processes react in the foreline at lower temperatures to produce porous tungsten deposits with SiHₓF_{y} and WF_{z} entrapments. Upon ambient exposure these highly porous deposits burst into flames and produce highly toxic HF fumes as well as emitting environmentally unfriendly SiF₄ gas.

Hazardous and solid generating exhaust effluents are typically carried through the foreline to the atmospheric pressure exhaust prior to being treated and abated to avoid hazardous emission. While atmospheric pressure abatement has been proven reliable and adequate for protecting the environment, it did not alleviate the cost, performance and safety deficiencies of solid growth and condensation in the sub-atmospheric foreline and at the pumps.

MKS Instruments has introduced a useful apparatus that protects forelines from adverse deposition of byproducts. This element is described in U.S. Pat. No. 5,827,370 and related publications. It implements a combination of pipeline heating and pipeline wall protection by inert gas blanket flow. While not solving the inherent need to abate solids away from the stream of exhaust line effluent that invention provides a mean to connect process chambers with abatement devices with low maintenance conduits. However, the design suggested by MKS is complicated and does not provide full protection for the conduit walls.

Accordingly, down stream lines (forelines) with improved performance and reliability are key for cost reduction, yield enhancement and improved uptime and safety of most CVD and etch processing equipment. Apparatus and methods should improve current unsatisfactory performance in the following scopes:
a. Downstream Pressure Control. Current mechanical throttle valve technology is slow, creates turbulences and becomes unreliable and maintenance intensive in cases where solid precipitation occur.
b. Backflow of downstream effluents and particle from the throttle valve area is a common problem. Also, upon significant chamber pressure change throttle valve oscillations may produce backflow.
c. Abatement of solids in the sub-atmospheric pressure region is desired to extend the lifetime of foreline components, extend maintenance schedule and reduce downtime, reduce the cost of maintenance and enhance safety. Condensation traps that are very common for treating condensates at the sub-atmospheric sections of downstream manifolds are mostly unsatisfactory, and in the case of reactive mixtures are also extremely unsafe.
d. Maintenance and Safety of current technologies is typically inadequate.
   Therefore, fast and simple maintenance of forelines to refresh the capacity of solid abatement elements without exposing personal and the environment to hazardous conditions is not available.

### SUMMARY OF THE INVENTION

It is the objective of the present invention to provide a method for downstream pressure control with fast response. It is another objective of our invention to provide apparatus and method for performing downstream pressure control without the usage of moving mechanical devices and with optimized and smooth flow passage. It is yet another objective of this invention to provide apparatus and method for suppressing backflow of effluent and particles from a foreline into deposition chambers.

In another aspect invention provides wall protection from growth of solid deposits in foreline conduits and chamber walls. It is an objective of this invention to combine effective and fast downstream pressure control, suppression of backflow and wall protection from growth of deposits with a variety of effective sub-atmospheric abatement methods, preferably for deposition and etch chambers.

It is an objective of our invention to enhance the safety of deposition systems. It is also our objective to reduce wear of foreline components such as pumps, gauges, sensors and vacuum parts and to substantially reduce the complexity and cost of maintenance of downstream pressure control apparatuses.

Accordingly, downstream lines (forelines) with improved performance and reliability provide one or more of the following features:
a. Downstream pressure control is implemented by setting at least two significant pressure-gradient-sections between the deposition chamber and the first vacuum pump and provide continuously controlled flow of gas into the section between the two gradients. This flow of gas impacts the effective pressure gradient at the outlet of the deposition chamber therefore controlling the flow of effluent out of the deposition chamber.
b. Pressure gradients are designed into the foreline to effectively suppress backflow of effluent and particulates. In addition, the pressure control method self-compensates and suppresses backflow by maintaining the pressure gradients over a wide range of flow changes and fluctuations.
c. Inert gas wall protection is implemented with pressurized permeable walls to facilitate uniform flow and smooth flow path as well as reduced complexity compared with existing methods.
d. Chemicals that can generate solid deposits or condensates are effectively extracted from the effluent at the sub-atmospheric pressure range close to the deposition chamber and upstream to the vacuum pumps. A variety of abatement techniques can be implemented by multiple apparatus designs. Flexibility of apparatus design and abatement method is provided by the pressure control and backflow suppressing components.
e. Enhanced safety and environmental protection is provided by effectively converting reactive chemicals into solid inert deposits and by producing these deposits as high quality films rather than powder or porous films and within a highly localized area. Substantially, only volatile hazardous materials are emitted into the atmospheric pressure exhaust where they can be abated, if necessary, by conventional atmospheric pressure abatement means.

The invention teaches the following apparatus and method. A standard processing (deposition, etching, etc.) chamber is connected to a downstream pressure control chamber (PCC) through a conduit and a flow restriction element (FRE). Typically, the FRE is built into the conduit to provide a smooth flow path with appropriate conductance. The PCC is preferably connected to a downstream vacuum pump through another FRE and optionally through a foreline conduit. The flow of effluents out of the deposition chamber creates substantial pressure gradients over the first and the second FREs. Therefore, the pressure in the PCC is lower than the pressure in the deposition chamber and higher than the pressure at the foreline leading to the vacuum pump when there is flow going through the system. The PCC is supplied with gas through one or more valves where one of the valves is preferably continuously proportionally controlled. Gas supply through the proportional valve is capable of raising the pressure inside the PCC above the level that is dictated by the flow coming out of the deposition chamber. The flow out of the process chamber into the PCC, which we call DRAW, is driven by the pressure gradient across the FRE between the process chamber and the PCC. Accordingly, increased PCC pressure induces decreased flow out of the process chamber. This reduced flow is compensated as the chamber pressure is driven upward to return to steady state since during the transient there is a mismatch between the FLOW into the process chamber and the DRAW out of the process chamber. Effectively, the pressure in the chamber is tweaked upward. Likewise, the process chamber pressure is tweaked downward when the flow into the PCC is reduced to effectively reduce the pressure inside the PCC. The pressure control is smooth and backflow is inherently impossible for as long as the PCC pressure never exceeds the process chamber pressure. Within a well designed apparatus, PCC pressure cannot exceed process chamber pressure as explained in the preferred embodiment section below. This Flow Controlled Draw (FCD) represents a significant improvement over prior art methods of gas ballast since the draw control flow of gas is introduced into the PCC and therefore has no impact on the composition of the process gas inside the process chamber. In addition, the draw is controlled by the pressure gradient over the FRE between the process chamber and the PCC while the FRE between the PCC and the pump is adequately selected to maintain the pump in the highly-preferred flow independent pumping speed regime.

Pressure control is preferably achieved by the following procedure:
a. Process pressure is controlled with the flow into the PCC set to provide an appropriate pressure control range.
b. A flow controlling device such as a proportional valve controls the inflow into the PCC. This device is controlled to maintain chamber pressure.
c. Deviation from process pressure set-point drives the PCC inflow appropriately to correct the deviation with appropriate control scheme, such as PID. Additional control scheme can be used to further enhance the speed of pressure control response, as described in the preferred embodiment, below.
d. Pressure control response time is dictated by the process chamber residence time. Likewise, transient process chamber fluctuations are also bound to chamber residence time. In contrast, proportional valves are capable of responding with millisecond response time. Accordingly, transient pressure fluctuations are suppressed by the FCD apparatus as they form and prior to reaching their full extent. This matched response between transient formation and correction is key for a smooth and converging pressure control.

Furthermore, pressure control does not involve moving mechanical parts (immersed in the flow of downstream reactive effluents and byproducts) overcoming four major drawbacks of current throttle-valve techniques. Accordingly, clogging, jamming of moving mechanical parts (also source for particulate generation), slow response and irregular flow path are avoided. In addition, the arrangement of the FRE/PCC/FRE/PUMP suppresses backflow of effluents and particulates from the foreline into the process chamber. Moreover, the PCC is the best location for ridding process exhaust effluents from all potential condensable (especially solid) byproducts.

Additionally, our apparatus invokes an exhaust effluent transport conduit with means for inert gas wall protection. This improvement that can be implemented to protect the wall of process chambers preferably utilizes double wall construction wherein the inner wall comprises permeable construction and the outer wall is constructed by conventional vacuum methods. The compartment between the inner and outer walls is pressurized with inert gas and the permeability accounts for a steady flow of gas through the inner walls. This flow of gas produces a continuous sweep of gas flowing away from the wall and effectively preventing reactive gasses from reaching the walls.

Solid producing chemicals can be extracted from the effluent stream by one or more of several methods. Solid films are encouraged to deposit on high surface area elements that are disposed within the abatement PCC. These high surface area elements typically comprise high conductance construction made from porous or rough material. Abatement elements are advantageously removable for ease and quickness of maintenance; Pluralities of abatement techniques that are known in the art are advantageously carried by the combination of PCC and high surface area element. In particular abatement processes are designed to improve the quality of growing films and avoid the growth of loose and porous deposits and powders. Means to achieve improved quality films during abatement are high temperature, plasma as practiced in the art and most advantageously the usage of additive reactive gas to promote the efficiency of the abatement process while also improving the quality of the produced film deposits.

Sub-atmospheric abatement processes are prone to amplify instabilities of foreline pressure and flow that adversely impact overall stability of deposition and etch processes. In particular, abatement process that generates excessive amounts of gaseous byproducts or eliminate substantial fraction of gas from the effluent by converting them into solid films fluctuates in response to fluctuation in the composition of effluents that are exhausted from the process chamber. For example, the flow of etch byproducts constantly varies as the process proceeds through heterogeneous stacks of layers and in particular when etch stop layers are involved or when the process approaches the end-point. CVD processes will encounter transition between nucleation steps and bulk deposition. Moreover, even when etch and deposition processes are presumed to be at “steady state” it is known in the art that substantial fluctuations of byproduct flow and consumption rates of reactants cannot be avoided.

When the effluent from a deposition chamber is subjected to foreline abatement, typically complex reactant molecules are converted into solid deposits and multiple smaller size molecules, For example, Tetraethoxysilane (TEOS) can be converted into SiO₂ film and byproducts such as H₂O, CO₂, CO etc. When provided with a reactive source of oxygen such as O₃ the abatement process produces 12 H₂O molecules and 8 CO₂ molecules from a single TEOS molecule while consuming only 9 ozone molecules (as well as converting one O₃ molecule into O₂). Accordingly, fluctuations and/or drifts in the partial pressure of TEOS can translate into ×2 times larger fluctuation in the foreline pressure and flow (upon efficient conversion of unused TEOS into SiO₂). Likewise, fluctuations in the partial pressure of etch or deposition byproducts can be amplified by the downstream abatement process and can adversely impact the stability of the whole process. This fluctuation amplification could be substantial even though the typical concentration of reactive gas within the process inflow is relatively low compared to carrier and inert gas components.

When sub-atmospheric abatement is carried out inside a PCC, fluctuations are suppressed by the action of the pressure controlling gas. Pressure controlling gas flowing into the PCC is controlled to maintain the pressure in the processing chamber at a desired set-point making fluctuations suppression optimized for sustaining the steady state of the process. Therefore, FCD enables sub-atmospheric abatement with suppressed impact of byproducts instabilities.

In certain FCD applications, the abatement related gasses such as O₃/O₂ mixture can entirely replace the inert gas and perform the pressure control. In other applications the PCC can accommodate multiple inlets for reactive and inert gasses all but one gas are introduced through ON/OFF valves while one of the gas inlets is introduced through a flow control device such as a proportional valve that is feedback-controlled to sustain the desired process pressure.

The objective of the abatement system is to rid process effluents from all potentially solidifying chemicals and to produce high quality solid deposits that are inert and safe inside the PCC. It is also the objective of our system to deposit the retained inert solids on a removable insert that can be taken out of the PCC in a quick, easy and safe manner during maintenance and replaced with a fresh insert. The abatement inserts should provide steady and dependable abatement performance for extended periods of time that will make them cost effective and should not produce any adverse effect (i.e. particle, contamination) on the process throughout the period between successive scheduled maintenance.

In another embodiment, a combination of PCC and wall protected conduit is implemented to provide pressure control and downstream delivery of exhaust streams to a downstream separated abatement chamber. In this case another FRE is installed downstream from the abatement chamber to maintain the pressure at the abatement chamber. This arrangement can be implemented to increase the capacity of abatement chambers to solid deposits. Preferably, the wall protected conduit prevents premature and uncontrolled growth of deposits on the conduit walls. The impact of byproducts fluctuation amplification inside the abatement chamber is still adequately suppressed by the ability of the PCC to quickly respond and maintain the pressure inside the process chamber.

In one aspect of this invention, a sub-atmospheric downstream pressure control apparatus is taught, comprising a first flow restricting element (FRE), a pressure control chamber (PCC) located in serial fluidic communication downstream from the first FRE, a second FRE located in serial fluidic communication downstream from the PCC, a gas source and a flow controlling device in serial fluidic communication downstream from the gas source and upstream from the PCC. Preferably, the flow controlling device comprises a proportional valve. In an additional embodiment the flow Control device preferably comprises a shut-off valve preferably in parallel fluidic communication with the proportional valve. In another objective of the invention the sub-atmospheric downstream pressure control apparatus preferably includes a reactive gas source connected in serial fluidic communication upstream from the PCC and an abatement element located within the PCC. In yet another embodiment a third FRE is preferably connected in serial fluidic communication downstream from the PCC, an abatement chamber is preferably connected in serial fluidic communication downstream from that third FRE, a reactive gas source is preferably connected in serial fluidic communication upstream from the abatement chamber and an abatement element is preferably located within the abatement chamber. In one preferred implementation of this a sub-atmospheric downstream pressure control apparatus is preferably located in serial fluidic communication upstream from the first FRE. The process chamber and the PCC are preferably formed as compartments within a single process vessel and the first FRE is preferably formed within the partition between the process compartment and the PCC compartment. Advantageously, the partition between the process chamber and the PCC is preferably substantially formed by the wafer support chuck. In another improvement the embodiment also includes provisions to preferably control the wafer support chuck temperature. In additional set-up an embodiment for preferably biasing the chuck with electrical potential is described.

In another preferred embodiment, a wafer processing apparatus comprising a process chamber, a process reactive gas supply line from a process gas source in serial fluidic communication upstream from the process chamber, an upstream flow control device located in serial fluidic communication upstream from the process chamber and downstream from the process gas source, a first flow restricting element located in serial fluidic communication downstream from the process chamber, a pressure control chamber (PCC) located in serial fluidic communication downstream from the first FRE, a second FRE located in serial fluidic communication downstream from the PCC, a gas source and a flow controlling device in serial fluidic communication downstream from the gas source and upstream from the PCC is disclosed. In one aspect the flow controlling device can preferably be a proportional valve. In another aspect the flow controlling device is preferably a proportional valve with additional shutoff valves in parallel fluidic communication to the proportional valve. The methods and apparatuses that are taught, in this invention preferably allow to control the pressure within a process chamber during processes such as CVD, PECVD, RIE, HDP-CVD and sputtering within the range better than ±3% and preferably better than ±1% range and most preferably within less than ±0.2% range.

In an aspect of the invention, a sub-atmospheric downstream pressure control apparatus comprises a first flow restricting element (FRE), a pressure control chamber (PCC) located in serial fluidic communication downstream from the first FRE, a second FRE located in serial fluidic communication downstream from the PCC, a gas source and a flow controlling device in serial fluidic communication downstream from the gas source and upstream from the PCC. Preferably, the flow controlling device comprises a proportional valve. In one aspect the flow control device preferably comprises a shut-off valve in parallel fluidic communication with the proportional valve. In another aspect the sub-atmospheric downstream pressure control apparatus preferably comprises a reactive gas source connected in serial fluidic communication upstream from the PCC and an abatement element located within the PCC. In another aspect the sub-atmospheric downstream pressure control apparatus preferably comprises a third FRE connected in serial fluidic communication downstream from the PCC, an abatement chamber connected in serial fluidic communication downstream from the third FRE, a reactive gas source connected in serial fluidic communication upstream from the abatement chamber and an abatement element located within the abatement chamber. In yet another aspect the sub-atmospheric downstream pressure control apparatus preferably includes a process chamber that is preferably located in serial fluidic communication upstream from the first FRE where preferably both the process chamber and the PCC are formed as compartments within a single process vessel and the first FRE is formed within the partition between the process chamber and the PCC. In one aspect the partition between the process chamber and the PCC is preferably substantially formed by the wafer support chuck. In another aspect the wafer support chuck preferably includes means to maintain the wafer at a desired temperature. In additional aspect the means to maintain the wafer at a desired temperature include a heater. In another preferred aspect the wafer support chuck preferably includes means to bias the substrate with electrical potential.

In an aspect of the invention, a wafer processing apparatus comprises a process chamber, a process reactive gas supply line from a process gas source in serial fluidic communication upstream from the process chamber, an upstream flow control device located in serial fluidic communication upstream from the process chamber and downstream from the process gas source, a first flow restricting element located in serial fluidic communication downstream from the process chamber, a pressure control chamber (PCC) located in serial fluidic communication downstream from the first FRE, a second FRE located in serial fluidic communication downstream from the PCC, a gas source and a flow controlling device in serial fluidic communication downstream from the gas source and upstream from the PCC. In one aspect the flow controlling device preferably comprises a proportional valve. In another aspect the flow control device preferably comprises a shut-off valve in parallel fluidic communication to the proportional valve. In another aspect the sub-atmospheric downstream pressure control apparatus further preferably comprises a reactive gas source connected in serial fluidic communication upstream from the PCC and an abatement element located within the PCC. In an additional aspect, the sub-atmospheric downstream pressure control apparatus preferably includes a third FRE connected in serial fluidic communication downstream from the PCC, an abatement chamber connected in serial fluidic communication downstream from the third FRE, a reactive gas source connected in serial fluidic communication upstream from the abatement chamber and an abatement element located within the abatement chamber. In yet another aspect a process chamber is preferably located in serial fluidic communication upstream from the first FRE and both process chamber and PCC are preferably formed as compartments within a single process vessel where the first FRE is preferably formed within the partition between the process chamber and the PCC. In one aspect, the partition between the process chamber and the PCC is preferably substantially formed by the wafer support chuck. In one variant the wafer support chuck preferably includes means to maintain the wafer at a desired temperature. In a preferred aspect, the means to maintain the wafer at a desired temperature preferably include a heater. In additional aspect, the wafer support chuck preferably includes means to bias the substrate with electrical potential. In an aspect of the invention the sub-atmospheric downstream pressure control apparatus is preferably applied for low pressure CVD (LPCVD). In another aspect, of the invention the sub-atmospheric downstream pressure control apparatus is preferably applied for reactive ion etching (RIE). In another aspect of the invention, the sub-atmospheric downstream pressure control apparatus is preferably applied for plasma enhanced CVD (PECVD). In yet another aspect of the invention, the sub-atmospheric downstream pressure control apparatus is preferably applied for high density plasma enhanced CVD (HDP-CVD). In another aspect of the invention, the sub-atmospheric downstream pressure control apparatus is preferably applied for sputtering. In an aspect of the invention, the sub-atmospheric downstream pressure control apparatus is preferably used for process pressure control with less than ±3% range and more preferably used for process pressure control with less than ±1% range and further most preferably used for process pressure control with less than ±0.2% range. In an additional aspect, the abatement element preferably comprises a heater. In yet another aspect, the abatement element preferably comprises a plasma source. In a preferred aspect, the abatement element preferably comprises a heater and the abatement element can be preferably heated to temperature exceeding 700° C. and more preferably heated to temperature exceeding 700° C. In a most preferred aspect, the abatement element preferably comprises a heater and the abatement element can be preferably heated to temperature exceeding 900° C. In an important variant, the abatement element preferably comprises a removable part. In another aspect, the sub-atmospheric downstream pressure control apparatus preferably includes a wall protected conduit that is preferably located in serial fluidic communication between the second FRE and the abatement chamber and a forth FRE that is preferably located in serial fluidic communication between the wall protected conduit and the abatement chamber. Preferably, the wall protected conduit comprises an external metallic pipe and an internal metallic pipe where the internal metallic pipe and the external metallic pipe create an annular space between the internal metallic pipe and the external metallic pipe and the annular space is preferably sealed at both ends. The internal metallic pipe is preferably gas permeable and the annular space is pressurized with inert gas.

In another aspect, wall protected conduit includes an external metallic pipe and an internal metallic pipe. The internal metallic pipe and the external metallic pipe create an annular space between the outer wall of the internal metallic pipe and the inner wall of the external metallic pipe wherein the annular space is sealed at both ends. The internal metallic pipe is gas permeable and the annular space is pressurized with inert gas.

In another aspect, the wall protected chamber includes an external metallic enclosure and an internal metallic enclosure. The internal metallic enclosure and the external metallic enclosure create an inner space between the outer wall of the internal metallic enclosure and the inner wall of the external metallic enclosure wherein the inner space is sealed from the internal space of the inner enclosure and is sealed from the space outside of the external enclosure. The internal metallic enclosure is gas permeable and the inner space is pressurized with inert gas.

In another aspect, a downstream pressure control method is taught including controlling a flow of process gas into a process chamber and providing a flow of gas into a pressure control chamber (PCC) wherein the PCC is connected in serial fluidic communication downstream from the process chamber and a first flow restricting element (FRE) is located in serial fluidic communication downstream from the process chamber and upstream from the PCC. Accordingly the pressure at the process chamber is controlled by adjusting the pressure in the PCC to impact the pressure gradient over the first flow restricting element. In one aspect, adjusting the pressure in the PCC preferably comprises directing a flow of gas through a flow controlling device into the PCC where the PCC is preferably connected in serial fluidic communication upstream from a second FRE and the flow of gas into the PCC preferably combines with the flow of process gas to determine the pressure gradient over the second FRE and to effectively adjust the pressure in the PCC. In yet another variant, the flow controlling device preferably adjusts the PCC pressure to control the process pressure preferably to substantially reach set process pressure within 25 msec or less and more preferably to substantially reach set process pressure within 10 msec or less. In another aspect the flow into the PCC preferably comprises a first component delivered through an adjustable device, a second component delivered through a shutoff valve, a third component delivered through a shutoff valve wherein preferably the second component substantially sets a desired steady state pressure, the first component is preferably used to provide fine pressure adjustment and the third component is preferably actuated to provide fast pressure increase and the second component is preferably shutoff to provide fast pressure decrease. In one aspect, a vacuum pump is preferably located in serial fluidic communication downstream from the PCC and the pumping speed of the pump is preferably optimized.

In another aspect, a method for sub-atmospheric reactive gas abatement is taught comprising providing a substantial pressure gradient at an inlet to an abatement space, providing a substantial pressure gradient at an outlet from the abatement space, flowing a reactive abatement gas into the abatement space and reacting the reactive abatement gas with process gas exhaust effluents to produce substantially stable and inert solid where the stable and inert solid is substantially localized within the abatement chamber. In one aspect the abatement is preferably enhanced at elevated temperature. In another aspect the abatement is preferably enhanced using CRISP. In yet additional aspect the abatement is preferably enhanced using plasma.

In one aspect, a method for sub-atmospheric reactive gas abatement comprises providing a substantial pressure gradient at an inlet to an abatement space, providing a substantial pressure gradient at an outlet from the abatement space, flowing a reactive abatement gas into the abatement space and reacting the reactive abatement gas with process gas exhaust effluents to produce substantially volatile effluent gas where the substantially volatile effluent gas is transported through the foreline and the pump substantially without further reaction and without further growth of film deposits. In a preferred method, the reactive gas preferably includes reactive silicon precursors and the reactive abatement gas preferably comprises reactive fluorine species. In another preferred method, the reactive gas preferably includes reactive tungsten precursors and the reactive abatement gas preferably comprises reactive fluorine species.

In another aspect, a method to protect internal vessel wall from substantial growth of solid films comprises flowing a substantially uniformly distributed inert gas through the wall and adjusting the temperature of the wall.

In another aspect taught by the invention, a wall protected process chamber comprises an external metallic enclosure, an internal enclosure disposed within the external metallic enclosure where the internal enclosure and the external metallic enclosure create a space between the outer wall of the internal enclosure and the inner wall of the external metallic enclosure and that space is vacuum sealed. The internal enclosure is gas permeable and the is pressurized with inert gas where the pressurized gas is flowing into the process chamber through the wall of the permeable internal enclosure.

### BRIEF DESCRIPTION OF THE DRAWINGS

The accompanying drawings, which are incorporated in and form a part of the specifications, illustrate the preferred embodiment of the present invention, and together with the description serve to explain the principles of the invention. In the drawings:

FIG. 1 depicts an illustrative cross-sectional view of a process chamber and downstream pressure control implemented with a “flapper” based throttle valve as known in the prior art.

FIG. 2 depicts an illustrative cross-sectional view of a process chamber and downstream pressure control using flow controlled draw (FCD) in accordance with the current invention.

FIG. 3 depicts a schematic (3a) and an illustrative cross-sectional view (3b) of a process chamber and downstream pressure control using flow controlled draw (FCD) wherein both the process chamber and the pressure control chamber (PCC) are implemented as compartments of a single vessel in accordance with the current invention.

FIG. 4 depicts an illustrative cross-sectional view of a wall-protected conduit in accordance with the current invention.

FIG. 5 depicts an illustrative cross-sectional view of a process chamber and downstream pressure control using flow controlled draw (FCD) with integrated abatement of solid byproducts in accordance with the current invention.

FIG. 6 depicts an illustrative cross-sectional view of a process chamber and downstream pressure control using flow controlled draw (FCD) with integrated abatement of solid byproducts wherein the abatement is performed in a downstream abatement chamber in accordance with the current invention.

FIG. 7, which is on the same drawing page as FIGS. 9 and 10, depicts a high area abatement element in accordance with the current invention.

FIG. 8, which follows FIG. 4, depicts an illustrative cross-sectional view of a process chamber and downstream pressure control using flow controlled draw (FCD), wall-protected conduit and a downstream abatement chamber in accordance with the current invention.

FIG. 9 depicts an illustrative cross-sectional view of a batch process reactor and downstream pressure control using flow controlled draw (FCD), wall-protected conduit and a detachable downstream abatement chamber in accordance with the current invention.

FIG. 10 depicts a high area abatement element designed for versatile and high temperature abatement in accordance with the current invention.

FIG. 11 depicts a high area abatement element designed for quick replacement in accordance with the current invention.

FIG. 12 depicts a high area abatement element designed for plasma based abatement in accordance with the current invention.

### DETAILED DESCRIPTION OF THE PREFERRED EMBODIMENT

### A. Downstream Pressure Control and Back-Flow Suppression

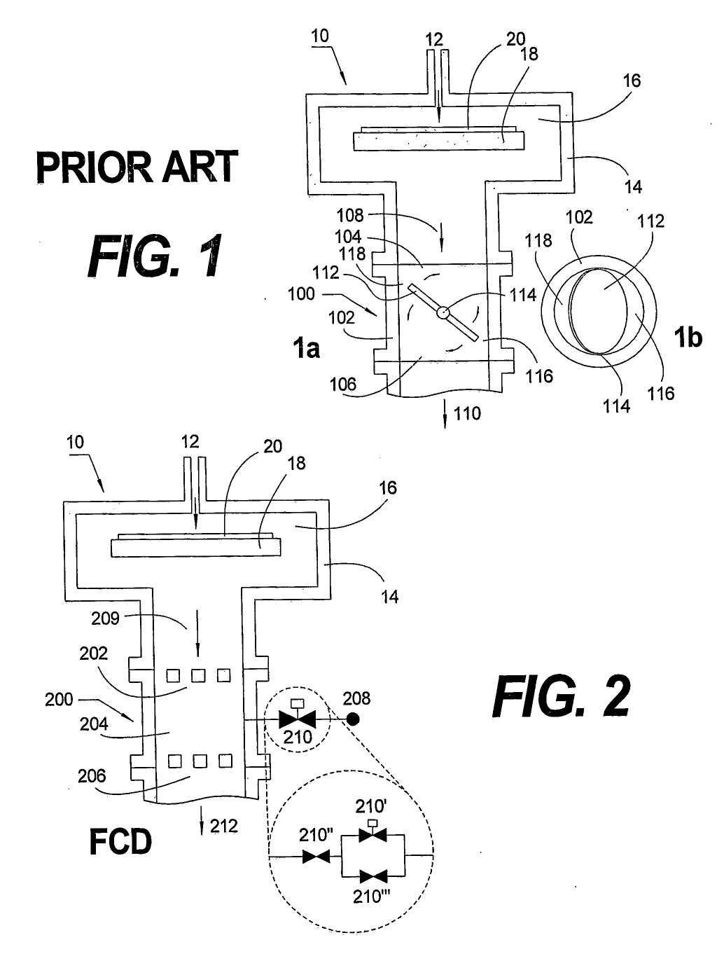

In an exemplary preferred embodiment (FIG. 2) Flow Controlled Draw (FCD) assembly 200 replaces prior art throttle valve 100 (FIG. 1) as the downstream pressure control device. A standard processing (deposition, etching, etc.) chamber, 10, is connected to a downstream Pressure Control Chamber (PCC), 204, through a conduit 209 and a flow restriction element (FRE) 202. PCC 204 is connected to downstream vacuum pump or foreline 212 through another FRE, 206. PCC 204 is supplied with gas through one or more valves where one of the valves (210′ in FIG. 2 inset) is proportionally controlled to deliver pressure control gas from source 208. In the simplest case of downstream pressure control that is illustrated in FIG. 2 an inert gas, 208, is supplied through one proportional valve, 210, that is feedback controlled to maintain the pressure in process chamber 10. Also depicted schematically in FIG. 2 are upstream process gas inlet 12, substrate support chuck 18 and substrate 20.

Process pressure is affected by the total flow of process effluents, the conductance of FREs 202 and 206, the flow of inert gas into PCC 204 and the pumping speed of the pump downstream from 212. Process pressure can be controlled at any desired pressure for any optimized value of total flow by appropriate selection of FREs 202 and 204 and the pumping speed of the pump. The range of inert gas flow into the PCC 204 is determined in the simple case of pressure control by the need to compensate for the maximum expected pressure fluctuations and by convenience. To add flexibility for pressure range adjustment without changing FREs 202 and/or 204 (which may be inconvenient) the pumping speed of the pump (dry pump or turbo pump or both) can be controlled by altering the speed of the pump(s) as was demonstrated recently. As can be understood by those who are skilled in the art, both FREs 204 and/or 206 can be replaced with an adjustable device such as a position pre-set throttle valve for added flexibility during process development. However, it is recommended that eventually, FREs 204 and 206 would be passive flow passage elements to accommodate a desired simpler, cheaper and more reliable apparatus preferably having no moving parts.

In the embodiments presented in this invention, downstream pressure control does not involve moving mechanical parts (immersed in the flow of downstream reactive effluents and byproducts) overcoming three major deficiencies of current throttle-valve techniques: (1) deposition on and jamming of moving mechanical parts (also source for particulate generation), (2) slow response and (3) irregular flow path causing disadvantageous turbulence. In addition, the unique design of the FRE/PCC/FRE/PUMP inherently suppresses back-flow of effluents and particulates from the foreline back into the process chamber. Finally, the PCC is the best location for ridding process exhaust effluents from all potential condensable (especially solid) byproducts that could further deposit on the foreline and pump with potential detrimental impact on performance, pump lifetime, safety and cost. That is, the PCC is where solid byproducts will be abated away from the exhaust stream. The FCD technique also advantageously suppresses and compensates for abatement related pressure fluctuations.

Back-flow from the PCC into the process chamber is avoided if the pressure gradient across FRE 202 is designed to exceed the largest expected pressure fluctuation. Accordingly, process pressure fluctuations cannot drive the pressure in the process chamber to reverse the pressure gradient and the direction of flow over FRE 202.

Process pressure fluctuations can be the consequence of less than perfect control over inlet process gas flow and temperature at various chamber locations. However, even if the inflow and temperature are ideally controlled, some inevitable sources of pressure fluctuations exist. For example, the change in reaction rate associated with the transient beginning and end of deposition and etch processes drive the composition of the exhaust effluent into unsteady ratio between unreacted chemicals and by-products. In another example plasma processes, in particular, mark a significantly different gas phase temperature change as the plasma is being ignited and when the plasma approaches steady state.

Practically, a downstream pressure control device is controlled to overdrive the corrective act and achieve faster pressure correction. For example, a throttle valve will be driven to respond to a pressure down fluctuation into a more flow-restricting position. The overdrive means that the throttle valve is positioned into a further restrictive position than the “perfect corrective act” position. The control method, for example a proportional, integral and derivative (PID) standard scheme will determine the overdrive. Clearly, the corrective act speed increases with the overdrive but, at the same time, unless the pressure-controlling device can respond without any delay, an oscillatory pressure response is inevitable. With this respect, the mechanical throttle valve device is substantially disadvantaged compared to the FCD device. The best available throttle valves are typically limited by their mass to response time on the order of 1 second (in many cases the need to accelerate and decelerate the motion of a heavy “flapper” limits the throttle valve response to more than 1 sec. and up to 5 sec.).

Process pressure fluctuations can be rectified with correspondence to the characteristic response of the process chamber. For example a typical 300 mm wafer size process chamber with 5 liter volume, 0.5 Torr process pressure and 500 sccm of flow is imposed with a 5% pressure change. Assuming that at most the chamber can be over-driven to use the entire range of 500 sccm flow to rectify the pressure fluctuation the pressure correction will occur on a time scale of ˜20 msec corresponding to a ˜0.165 scc (standard cubic centimeters) of gas that is added or removed from the chamber to correct the pressure fluctuation.

Throttle valves can be usefully operated within the range of 10%-90% conductance corresponding to ±40% around an optimized 50% position. Assuming a pressure independent conductance this range corresponds to a 10-90% flow or 100-900 sccm range for the above given example. Likewise, pressure correction can be set to ±400 sccm and the response time to correct for a 5% pressure fluctuation will be accordingly ˜25 msec. However, throttle valves are mechanically limited to slow response time within the range of 1-5 seconds for a necessary 40% conductance swing. As a result, the ability of throttle valves to overdrive pressure correction is limited by the speed of the throttle valve. A 1 second of fluctuation correction time is not acceptable for most critical applications.

In contrast, the FCD is driven by gas flow into a PCC. In the preferred pressure control method the pressure within PCC 204 is determined by the flow of process gas and the flow of gas from source 208. Preferably the FCD flow is set to provide the range of PCC pressure adjustment that is required to overcome pressure fluctuations during process. For example, within the above given example the process pressure of 0.5 Torr is set with a steady state PCC pressure of 0.25 Torr that corresponds to a total flow of 1000 sccm of which 500 scc come from the process and 500 sccm come from 208. Valve 210 (FIG. 2) is implemented with an array of 3 valves as depicted in the inset of FIG. 2. PCC pressure is maintained by a steady state flow of 500 sccm controlled by proportional valve 210′. This flow can be terminated by shutting valve 210″ of to obtain a maximized PCC pressure down overdrive. Maximized PCC pressure up overdrive can be obtained by opening shutoff valve 210′″ to substantially increase the flow of gas into the PCC. For example, a 2000 sccm can be driven into the PCC when valve 210″ is actuated open. At a typical 5 liter volume the PCC can reach a minimum pressure of ˜0.125 Torr (valve 210″ is shut) within ˜75 msec. Overdriving PCC pressure to ˜0.5 Torr can be driven within ˜40 msec. These PCC pressure points correspond to 100% and 0% throttle valve equivalent flow restrictions, respectively. Accordingly, the response of a FCD device is significantly faster and much better matched to the response time of the process chamber than the throttle valve response.

With a FCD device the corrective act can be overdriven substantially without any adverse impact on performance since the proportional valve, for example, an “of the self” solenoid or piezo-electric driven valve is capable of complete range swing within 1-25 msec (depending on the type of valve). It is recommended in the preferred embodiment of this invention to operate the proportional valve at the mid-point of it's full swing over a range covering ±25-35% of the swing for the full range of required pressure control. The range of flow into the PCC is easily set, as necessary, by adjusting the pressure of flow controlling gas behind the proportional valve. Accordingly, in the recommended preferred embodiment the PCC is substantially overdriven to substantially overdrive the corrective act of the downstream pressure control. When the desired pressure is reached or appropriately approached (for example, within a certain pre-set ΔP) the PCC is substantially overdriven the other way to overdrive the PCC pressure back to the “perfect corrective act”. For example the pressure is controlled by proportional valve 210′ within the pressure fluctuations below 1% while valve 210″ is open and valve 210′″ is shut. Beyond 1% pressure fluctuations a repetitive set of (210′/hold; 210″/shut); (210′/hold; 210″/open; 210′″/open) is iterated to corrected a process pressure up swing while a repetitive set of (210′/hold; 210″/open; 210′″/open); (210′/hold; 210″/shut) is iterated to correct a pressure down swing.

With excessive overdrive, the PCC pressure can be driven to exceed the pressure in the process chamber and induce disadvantageous backflow in the case of positive corrective-act overdrive (i.e. when (210′/hold; 210″/open; 210′″/open) is operated). To prevent this possibility the overdrive time response of the PCC pressure increase is maintained to always be slower than the response time of the chamber and the pressure measurement system.

While many processes do not need an ultra-fast pressure control response some critical processes will greatly benefit from the FCD arrangement depicted in FIG. 2 inset and described above. For example, reactive ion etching (RIE) processes where substantial reactant/by-products balance shift is encountered while the process approaches endpoint or when the etch process begins a partial penetration into an etch stop layer. A significant etch process conditions shift due to uncontrolled drift of process pressure can occur within the last several seconds of the process with adverse impact over uniformity and reproducibility and with acute pattern dependence. These “micro-loading” effects can be suppressed by reduced etch rate, increased chemicals flow rate, improved pressure control, or any combination. Improved pressure control is the most preferred remedy baring no throughput penalty and the lowest cost burden.

If process pressure is P and the pressure fluctuations in the chamber are in the range of ±ΔP the pressure at the PCC, P_{CCP} is conveniently set at P_{PCC}≦P−ΔP. This settings prevents backflow under any conditions by default since the pressure at the PCC is, by design, never higher than the pressure at the chamber. For example P_{CCP}=P−nΔP where n>1 ensures that flow is always directed downstream. Given process effluent throughput Q the conductance of FRE 202 (FIG. 2) between the process chamber and the PCC, C₁ is given by C₁=Q/(P−P_{PCC}). PCC inert gas control throughput, Q_{PCC} combines with process exhaust throughput Q and flows from the PCC to the pump passing through second FRE 206. The conductance of second FRE 206 is given by C₂=(Q+Q_{PCC})/(P_{PCC}−P_{PUMP}). For most practical reasons the flow in the system is viscous and therefore the conductance values of the FREs depend on the pressure. However, per desired process pressure and anticipated pressure fluctuations the geometry of each FRE can be evaluated to determine the estimated working point of the system.

Flow range of inert gas into the PCC is determined by anticipated ±ΔP range. Qualitatively, if the pressure in the process chamber fluctuates down, PCC pressure should go up to reduce the flow from the process chamber to the PCC (the “DRAW”). Note that initially an automatic pressure correction action initially occurs since a pressure drop in the process chamber causes ΔP=P−P_{PCC} reduction and consequently a reduced Q out of the process chamber. PCC pressure change will lag behind process chamber pressure change because P_{PCC} has contribution from the PCC inert gas flow.

Process pressure fluctuations originate from fluctuations of inlet flow of effluents or from fluctuations of outlet flow of effluents that can be caused by fluctuations of byproduct generation, temperature or C₁. Accordingly, the relation between P fluctuations and P_{PCC} correction is specific to chamber design and process parameters and is highly convoluted. Therefore, the proportional valve that determines Q_{PCC} and P_{PCC} is controlled to sustain process pressure P through a feedback loop that minimizes ΔP. Only rough estimate is necessary for initial setting of appropriate P_{PCC} working point and range. For example, if anticipated pressure fluctuations are ±ΔP, a rough assumption can be made that PCC need to be able to vary P_{PCC} by the same ±ΔP. For fast response of the proportional valve it is advantageous to set the flow of inert gas into the PCC in the range of 2ΔP±2ΔP. Accordingly, at ˜50% opening, the proportional valve will provide Q_{PCC} to maintain ˜2ΔP of pressure at the PCC above the pressure that would have been maintained if Q_{PCC}˜0. However, other configurations may be implemented per specific cases such as an arrangement where some of the inert gas flow to the PCC does not go through the proportional valve and therefore the control of Q_{PCC} (especially when the range of fluctuations is small) can be made with better precision and speed as depicted in FIG. 2 inset and explained above.

Once the range of Q_{PCC} is estimated, the geometry of C₂ can be estimated with sufficient precision to determine adequate mechanical design. Note that exact determination of Q_{PCC}, C₁ and C₂ is not crucial since final pressure control is determined by a feedback loop. In fact, the design of the initial setting resembles conventional designs with throttle valve based downstream pressure control where it is desired that hardware design position process working point at around 50% open throttle valve under given process Q. While throttle valves are sometimes perceived as if they have a wide design window for chamber outlet conductance, it is known in the art that throttle valve performance is severely deteriorated if the “flapper” is set to move outside of the range between 10%-90% (i.e. 50%±40%) and preferably 25-75% opening (i.e. 50%±25%).

It is also possible to conveniently tweak the system to operate around optimized working point by adjusting the pumping speed of the pump, as described in U.S. Pat. No. 6,316,045. Pumping speed reduction of turbo molecular pumps and other mechanical pumps can be achieved by speed control. Attempts to use pumping speed control for downstream pressure control were in general unsuccessful due to problematic response time effects. However, the technique is suitable for predetermined reduction of pumping speed. In summary, while pumping speed control is typically inadequate to be a throttle valve alternative, it can certainly add advantageous flexibility to designs of downstream pressure control systems implementing either conventional throttle valve techniques or the FCD technique described here, especially during process and hardware optimization stages.

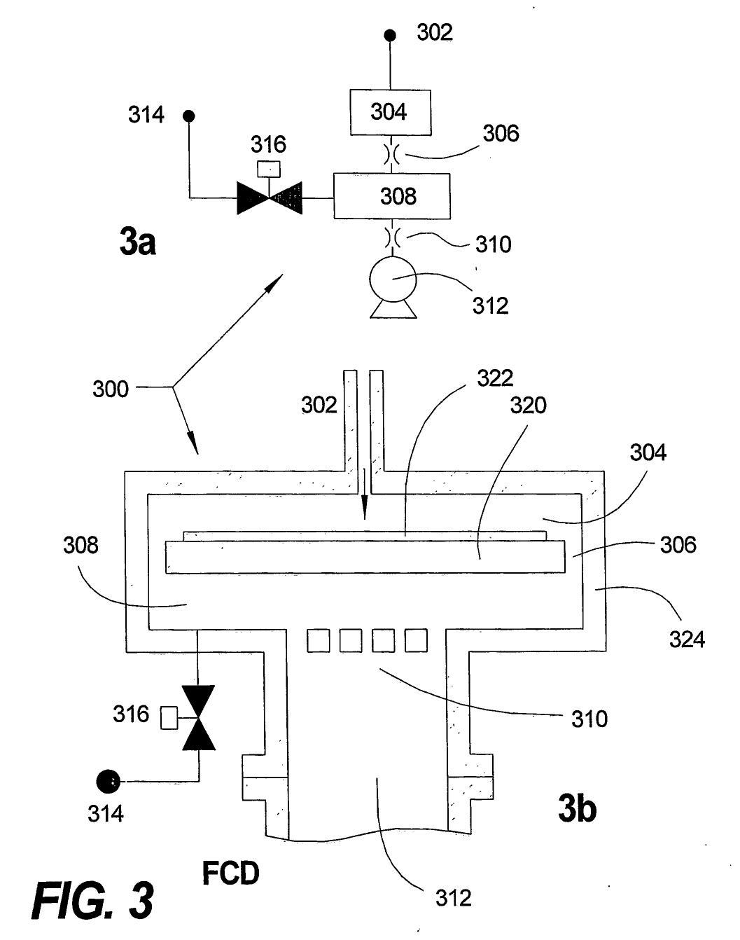

Additional embodiment in accordance with the present invention is depicted in FIG. 3. FIG. 3a illustrates the general FCD design and serves to better explain embodiment 300 depicted in FIG. 3b. FCD is implemented in a process vessel by creating a process compartment 304 and a PCC compartment 308. In the case example depicted in FIG. 3b the wafer support chuck 320 separates vessel 324 into process compartment 304 and PCC compartment 308. Process gas is supplied by the upstream manifold 302 (represented schematically) as commonly practiced in the art. FRE 306 is formed between vessel wall 324 and chuck 320. PCC outlet FRE 310 is positioned downstream to PCC 308. Pressure control gas is supplied from source 314 and controlled by valve 316. The effluents are then directed into a foreline or a vacuum pump as represented schematically by 312. Embodiment 300 represents a substantial reuse of existing process chamber elements with advantages such as lower-cost and smaller size but disadvantages such as need to redesign the process chamber and a more cumbersome access to abatement elements if they are located within the volume of 308 (see description below).

Flow restriction elements (FRE) are substantially more flow restricting with substantially smaller volume compare to chambers or compartment. While the distinction is mainly quantitative, flow systems are often described, for better clarity, as combinations and networks of “ideal” chambers and ideal FREs. An ideal chamber has no flow restricting associated with it and an ideal FRE has no volume associated with it. Many FRE designs are practiced in the art and are known to those who are skilled in the art. The choice of FRE design for FREs such as 202, 206, 306 etc. should be based on convenience, price and size usually with substantially insignificant impact on performance.

### B. Wall Protected Conduit

While not solving the inherent need to abate solids away from the stream of exhaust line effluent the “virtual wall” invention discussed in the introduction provides a mean to interconnect process chambers and abatement devices with low maintenance conduits. However, the design suggested by MKS is complicated and does not provide full protection for the conduit walls. While this element is not a crucial part of our system it may be convenient to use it in some applications where consideration of space, convenience or safety may dictate physical separation between the process chamber and the PCC or in cases wherein abatement will be carried outside of the PCC in a downstream additional chamber.

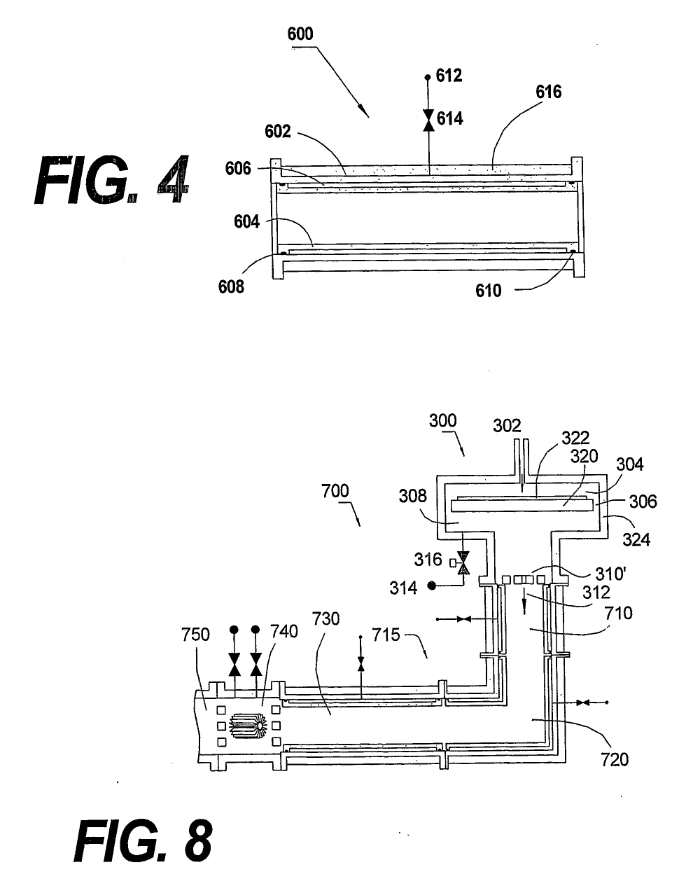

Accordingly, MKS (HPS) made “Virtual Wall™” products, in combination with HPS's line heaters such as series 45 heaters are recommended for extended flexibility in designing the embodiment according to this invention. However, in many cases the design that was patented by MKS does not provide satisfactory results. In these cases this invention further teaches an advantageous embodiment whereat the discrete implementation of MKS is replaced by the arrangement depicted in FIG. 4.

In this embodiment the conduit 600 is composed of a standard vacuum stainless steel pipe 602 that is lined with an inner pipe 604 that is cut to fit. Inner pipe 604 is made from a permeable (porous) metal or ceramics. The OD of the inner pipe 604 is smaller than the ID of outer pipe 602. The ends of inner pipe 604 are terminated with a lip that makes a tight fit to the ID of outer pipe 602 directly or with the assistance of elastomer or metallic gaskets 608 and 610. Inert gas 612 is pressurized through a standard fitting into annular gap 606 between outer and inner pipes 602 and 604, respectively, and a flow of gas leaks into the foreline that is confined inside inner pipe 604. The permeability of inner pipe 604 is made to achieve a desired inert gas flow rate that is adequate to maintain a sheath of inert gas close to the inner wall of pipe 604 and therefore deter the reactive effluents away from the wall. Accordingly, wall protection is established similar to the design suggested by MKS but with improved uniformity and simpler hardware. Increased efficiency of wall protection can lend itself for effective wall protection while reducing inert gas inflow into the wall-protected-conduit, therefore minimizing the effect of wall protection apparatus 600 on downstream flow. Line heating 616 can be accomplished by conventional foreline heaters (available from multiple manufacturers such as MKS, Norcal, Watlow, A&N, Briskheat, etc.) or by directly heating the inner tube.

### C. Abatement

A major object of this invention is to remove (abate) solid reaction byproducts away from the stream of process gas effluent, therefore protecting foreline pipes and elements (valves, pumps) from accelerated deterioration, clogging, breakage and particle generation. The properties of the PCC, as described above, make it a preferred place to perform this abatement process since the design of the PCC eliminates backflow and therefore can be made to accommodate additional reactive gasses that can be introduced into the PCC to induce efficient reaction with effluent components to promote efficient deposition of the solids on surfaces available inside the PCC. Additionally, gasses that may be required to sustain plasma to destruct the reactive effluents and to induce deposition and retention of solids inside the PCC can also be conveniently provided into the PCC without feeding back into the process chamber. Finally, abatement process that generates excessive amounts of gaseous byproducts may cause pressure fluctuations in the PCC. The effect of these fluctuations on the process pressure can be handled with the feedback control in the same manner as process chamber related pressure fluctuations are handled without any additional hardware. Similarly, possible PCC pressure fluctuations related to PCC temperature fluctuation that may result from the abatement process or from implementation of plasma are baffled by the pressure control and the ability to design, if necessary, more than one PCC in the foreline, as detailed below.

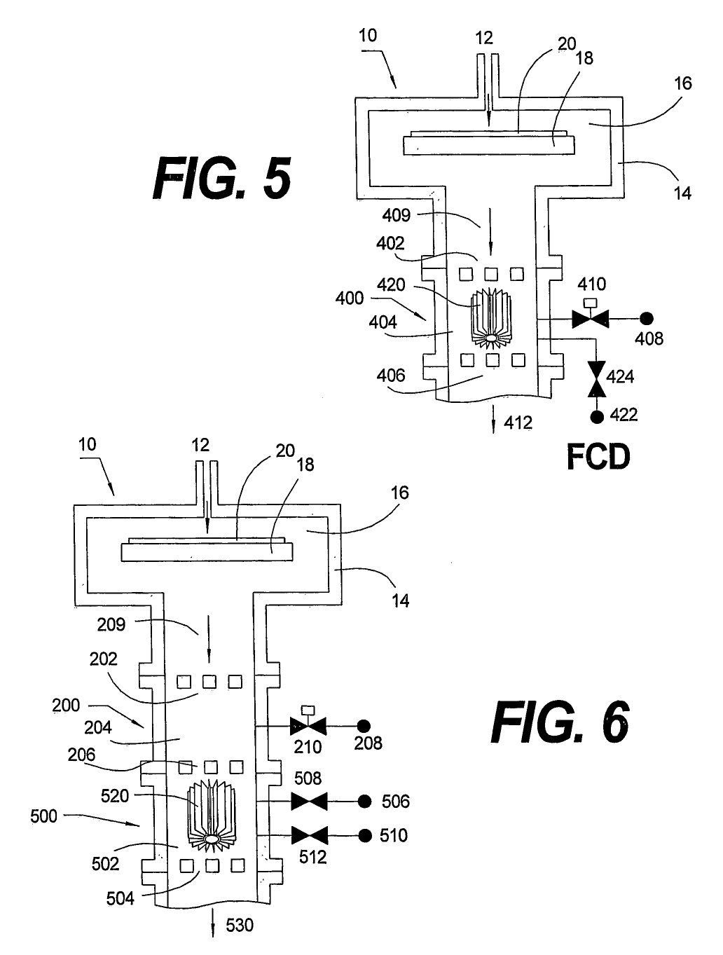

In certain applications, the abatement related gasses, i.e. an O₃/O₂ mixture, can entirely replace the inert gas and perform the pressure control. In other applications the PCC can accommodate multiple inlets for reactive and inert gasses all but one gas are introduced through shutoff valves and one gas that is the pressure control gas is introduced through the proportional valve that is feedback-controlled to sustain the desired process pressure (FIG. 5).

FIG. 5 depicts schematically a FCD implementation 400 with abatement element 420 located inside PCC 404 volume. Exhaust effluents 408 pass through inlet FRE 402 into PCC 404 and though outlet FRE 406 into the downstream foreline or pump represented schematically by 412. Pressure control is performed through valve (or valves arrangement) 410 with pressure control gas (inert or reactive) 408. In addition, reactive gasses may be supplemented through shutoff valve 424 from source 422. Source 422 and valve 424 represent schematically one of possibly several reactive gas inlets to promote the best abatement process inside PCC 404. Abatement element 420 preferably has high surface area achieved by a porous material construction or a roughened surface or both. Abatement surface is preferable removable and could be heated, if necessary.

In another preferred embodiment depicted in FIG. 6 the abatement is carried in a separated abatement chamber, 500, located downstream from PCC 200. Effluents mixed with pressure controlling gas enter abatement chamber 500 through FRE 206 and exit through FRE 504. Abatement element 520 is constructed as described above in reference to element 420 (FIG. 5). Reactive gasses are introduced through shutoff valves such as 508 and 512 from reactive chemical sources such as 506 and 510. Reactive gas manifolds 506, 508 and 510, 512 are exemplary for a manifold that can include only one reactive gas inlet or several as needed to optimize abatement performance.

The objective of the abatement system is to rid process effluents from all potentially solidifying chemicals and to produce high quality solid deposits that are inert and safe inside the PCC. It is also the objective of our system to deposit the retained inert solids on a removable insert that can be taken out of the PCC in a quick, easy and safe manner during maintenance and replaced with a fresh insert. Used inserts will be preferably cleaned in a safe and environmentally acceptable manner, outside the fab, or in some instances will be disposed in a safe and environmentally acceptable manner. Maintenance cost should be minimal. The abatement inserts should also provide steady and dependable abatement performance for extended periods of time that will make them cost effective and should not produce any adverse effect (i.e. particle, contamination) to impact the process throughout the period between successive scheduled maintenance.

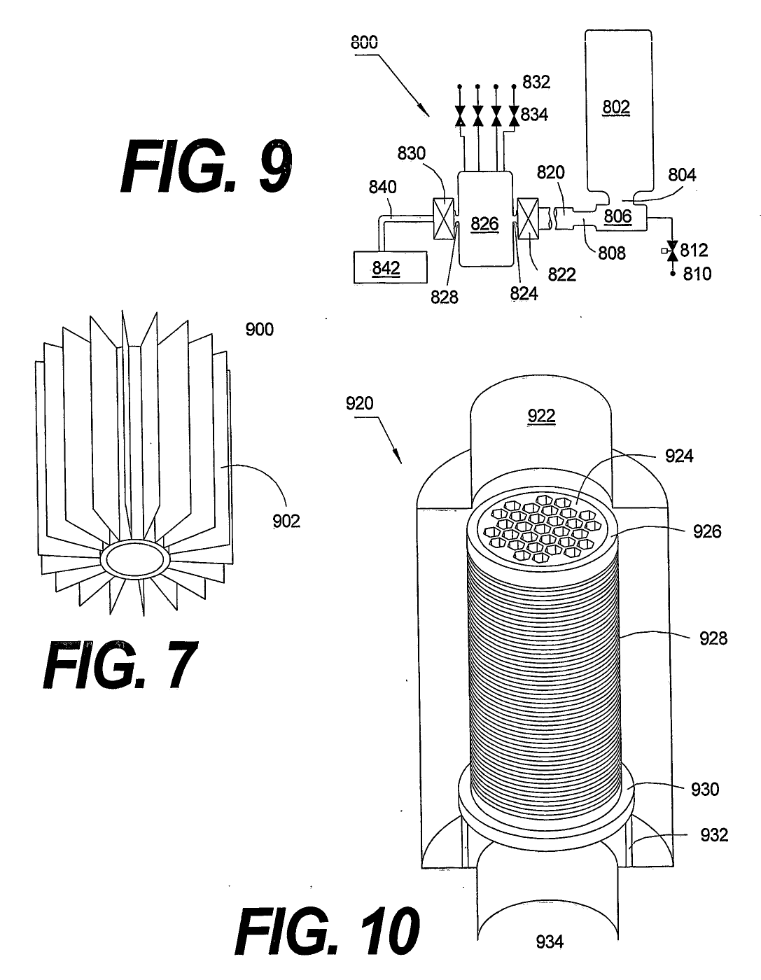

One such insert is depicted in FIG. 7. Porous or surface roughened substrate made from metal or ceramics is implemented to provide substantial area for material deposition. Porous material can advantageously enhance the efficiency of surface reactions of impinging reactive molecules by pore trapping. Reactive molecular species that impinge on the opening of a pore are subjected on the average to many collisions with the walls of the pore before they emerge out and therefore, reaction probability as compared to a flat surface is substantially enhanced. Pore size may vary depending on the applications. The useful range (˜50% porosity) is typically around 10 μm pore size where surface areas can be as high as 200 cm²/cm³. In this range the conductance into macroscopically large pores is not a significant factor. In addition, the capacity of the porous material to abate solid materials is related to the ability to retain the films that are grown into the pores. When the pores are filled up, the insert must be refreshed or changed. For example if a 10 μm pore size is being used and the total volume of porous material that is conveniently arranged in plates or fins 902 within element 900 (FIG. 7) is 2000 cm³ the total capacity of the insert for SiO₂ generated from abatement of Tetraethoxysilane (TEOS) is ˜100 cm³. This capacity translates into a capacity to abate ˜1.15 liters of TEOS, assuming that the pores can be deposited half the way through without adverse effect on abatement efficiency.

Higher capacity for abatement of chemicals such as TEOS can be achieved by another preferred embodiment, 700, depicted in FIG. 8. For example, FIG. 8 implements the PCC similar to the embodiment depicted in FIG. 3 and described with reference to FIG. 3. Accordingly, PCC 308 is implemented as a compartment within vessel 324. PCC 308 may include an abatement element (not shown). In addition or as an alternative, the abatement is carried further downstream within abatement chamber 740. Adverse effluent reaction and solid film deposition in the foreline leading to abatement chamber 740 is suppressed by wall-protected conduit elements. For example, 3 elements, 710, 720 and 730 are depicted in FIG. 8. For example the wall protected elements are implemented as described with reference to FIG. 4, above. Pumps and additional downstream foreline are represented schematically by 750. According to preferred embodiment 700 abatement can include larger volume of chamber 740 with higher abatement capacity. For example, a 10 liter abatement element will allow a 5.75 liter TEOS abatement capacity.

In another example of the preferred embodiment, 800, (FIG. 9) a much higher abatement capacity is implemented downstream from a batch processing reactor such as a vertical furnace LPCVD reactor. Reactor 802 is connected through FRE 804 to PCC 806 for FCD downstream pressure control in accordance with the present invention. Process pressure is controlled by the flow of gas from source 810 through a proportional valve (or valves arrangement as described above with reference to the inset in FIG. 2) 812. Effluents exit PCC 806 through FRE 808 into wall protected conduit 820 (shown only schematically) and enter abatement chamber 826 though isolation gatevalve 822 and FRE 824. Reactive gasses are supplied to abatement chamber 826, for example from sources 832 and through valves 834. The exhaust gas further exit abatement chamber 826 through FRE 828 and isolation gatevalve 830. Additional foreline 840 and pumps 842 are shown only schematically. In embodiment 800, very large capacity for abatement of solids can be advantageously implemented to accommodate long maintenance intervals with such high maintenance load reactors that are used, for example, for thick film deposition over multiple substrates. Maintenance procedure is carried by isolating abatement chamber 826 with both isolation gatevalves 822 and 830. Then the assembly that includes 822, 824, 826, 828 and 830 is separated and carried outside of the fab where it is maintained safely by an appropriate procedure. Alternatively, since the solid inside abatement chamber 826 is not hazardous, isolation gatevalves 822 and 830 can be left on the system to isolate both the upstream and the downstream of the system from ambient exposure. Fast system recovery is established quickly with the installation of a fresh 824, 826, 828 assembly.

In some cases, such as when the abated solid is SiO₂ or W, an in situ procedure can be applied to refresh the abatement element. For example, abatement element 520 (FIG. 6) can be refreshed by an in situ process to remove the solid deposit from 520. For example, ClF₃ gas can be introduced into abatement chamber 502 while inert gas is flown through the system to substantially suppress (if necessary) backflow of harsh ClF₃ into the space above FRE 206. This procedure can be used to remove SiO₂, W and other solid films that can make volatile fluoride species from element 520 and can refresh the abatement chamber without the need to remove and replace element 520.

In yet another alternative abatement method, the abatement can produce a volatile byproduct to eliminate the potential of solid byproduct growth in the foreline and pumps while converting the reactive effluent into volatile, non reactive mixture of gas. For example, a reactive effluent mixture containing tungsten hexafluoride (WF₆) and silane (SiH₄) is effectively neutralized (in a sense that makes it a non reactive effluent mixture that is not capable of growing solid deposits in the foreline) by the use of reactive fluorine containing gas such as ClF₃ (or plasma activated NF₃) to chemically convert SiH₄ into SiF₄ and solid W (if generated from direct reaction of WF₆ and SiH₄) back into WF₆. The mixture WF₆/SiF₄ and fluorine containing gas is not capable of generating solid deposits in the foreline at customary foreline temperatures. The volatile mixture WF₆/SiF₄ is further treated using atmospheric abatement is known in the art.

For a given porosity the capacity for solid retention is independent of pore size. However, the enhancement of reaction efficiency for a well-designed insert (explained below) strongly depends on the surface enhancement. For example if the porous material is made from ⅛″ thick plates with 10 μm pore size and 50% porosity, the surface area enhancement is approximately ×30 which accounts for a substantial advantage. Limitations on the usefulness of small pores are related to step coverage capability of the particular chemistry used for abatement. Porous materials with large pores leading to smaller pores are advantageous for enhancing reactivity of the abatement process. Other factors that determine abatement efficiency are surface temperature of the porous media, the reactivity of the reactive components from process effluents and the reactivity of the reactants that are provided into the PCC for abatement. In addition, the efficiency scales with the residence time of the effluents inside the PCC. Since systems with multiple downstream chambers are possible, residence times inside the separated abatement chambers, downstream to the PCC, can be advantageously designed to provide high conversion efficiencies for the abatement process.

In a specific example, TEOS may be converted thermally (by pyrolisys) on tungsten surfaces held at ˜800° C. into SiO₂C₂H₄, C₂H₅OH and H₂O. However, this reaction is not very efficient with reactive sticking probability of ˜3×10⁻⁵. Typical partial pressure of TEOS in the exhaust effluent from an LPCVD is 0.01-0.10 Torr (10¹⁴-10¹⁵ molecules/cm³) and the total pressure in the PCC is, for example, ˜0.50 Torr. Accordingly the flux of TEOS is on the order of 10¹⁸-10¹⁹ molecules/cm² per sec. If the volume of the PCC is 10 liter and the flow is 1000 sccm the residence time in the PCC is ˜0.4 sec. Given the surface area of the insert at ˜400000 cm² and the total No. density of TEOS molecules in the PCC (without reaction) of N˜10¹⁸-10¹⁹ the rate of TEOS molecules reaction, k, is given by:

$$k \approx \frac{ⅆ N}{N ⅆ t} \approx 400000 \times 2.5 \times {10}^{- 5} \times {10}^{19} / {10}^{19} \text{/} sec = 10 \text{/} sec \qquad ( 1 )$$

TEOS concentration after passing through the abatement chamber is C=C₀exp(−kτ) ˜0.018 C₀ (1.8%). Without the effect of surface enhancement the concentration of emerging TEOS is expected to be as high as 87% of the original concentration C₀.

Abatement of TEOS is an ongoing difficult technological challenge and many solutions have been suggested in the past. However, none of these solutions have proven to be satisfactory, cost-effective, safe and convenient as desired. In particular TEOS polymerization creates solid deposits that clog pipelines and destroy pumps, valves and vacuum gauges. These deposits are accounted for reduced process yield by generating particles. In addition, the solid and liquid polymer deposits are toxic and flammable posing safety hazard upon maintenance. TEOS is used extensively in the semiconductor industry and other industries (such as glass molding and optical waveguide fabrication) to deposit silicon oxide and doped silicon oxide films. Typical semiconductor applications implement CVD and PECVD of TEOS to grow films in the 0.5-1 μm (micron) range. Reactor design and deposition techniques vary and span the pressure range from 100 mTorr to 1 atmosphere.

Many techniques implement ozone and oxygen to improve film quality and provide higher deposition rates at lower temperatures. Typical pyrolisis temperatures are in the range from 650-900° C. PECVD can be carried at relatively lower temperatures. Ozone assisted reactions were demonstrated with high rates in the temperature range from 375° C. and up. For the purpose of efficient TEOS abatement the above described example indicates that efficient and satisfactory abatement can be implemented without the addition of reactive abatement gas if the porous insert is heated at temperatures equal or higher than 800° C. Facilitating these temperature require direct heating of the insert and mounting techniques that provide minimal thermal contact between the insert and the PCC walls. Other implementation may apply externally heated tube made of quartz or ceramics similar to conventional furnace tubes. However, given the complexity to implement such high temperature abatement it is desired to abate TEOS at lower temperatures.

One such advantageous embodiment implements the reaction of TEOS and ozone to achieve TEOS conversion into high quality SiO₂ films at substantially lower temperatures. Additionally, TEOS can be reacted with other strong oxidants. The unidirectional characteristic of the PCC enables the usage of many chemicals that can be added to the PCC through valves and provide enhanced TEOS reaction. For example, Catalyzing Reactions for Surface Induced Processes (CRISP) that were patented by the inventor of this invention and assigned to the same assignee. For example, a low temperature TEOS abatement process implements CRISP between ozone and a reactive hydrocarbon such as C₇H₁₆ (n-heptane) or with reactive oxidizing molecules such as ozonides to enhance the conversion rate of TEOS into SiO₂ at lower temperatures. In a different embodiment the conversion of TEOS into volatile SiF₄ is carried by the addition of reactive fluorine containing gasses such as ClF₃ or plasma activated NF₃.

In further embodiment an abatement element is implemented using a heatable conduit such as element 920 depicted in FIG. 10. For example a honeycomb shaped passage 924 is made of porous aluminum or other materials and contained within tube 926. Heater 928 is attached to tube 926. The assembly is mounted on flange 930 made from poorly thermally-conducting material such as stainless steel. Flange 930 is further mounted inside abatement chamber 920 using low thermal conductivity posts 932 which are made from poorly conducting material such as stainless steel, fused silica, ceramics, etc. Effluents are directed into inlet 922 and pass through the honeycomb 924 to emerge out from outlet 934. Alternatively, honeycomb 924 can be made from pyrolytic graphite coated with SiC and tube 926 can be made from SiC or AlN to provide construction with high temperature endurance. Element 920 is maintained at relatively high temperatures to enhance the abatement process. With the implementation of high thermal endurance materials this arrangement can tolerate insert temperatures in excess of 1000° C. Graphite or SiC coated graphite inserts are a convenient choice for this implementation since they are cheap and light weight and can be easily cleaned in HF solutions (multiple times) to remove SiO₂ films. Graphite can be manufactured with tailored porosity using available techniques. Alternatively, the insert can be molded from porous alumina, zirconia or other ceramics. The walls of the PCC preferably implement inert gas wall protection and the deposition is limited to the porous walls of element 924 that is machined or molded as a honeycombed to increase the effective exposed area. The walls of the PCC may need cooling to compensate for excessive heat transfer through the effluent passing gas. A heating wire with a preferred rectangular cross-section is wrapped around the SiC or AlN tube body inside grooves. The heater wire is electrically connected to a standard electrical feedthrough for vacuum insertion of electrical current and temperature measurement sensor signal.

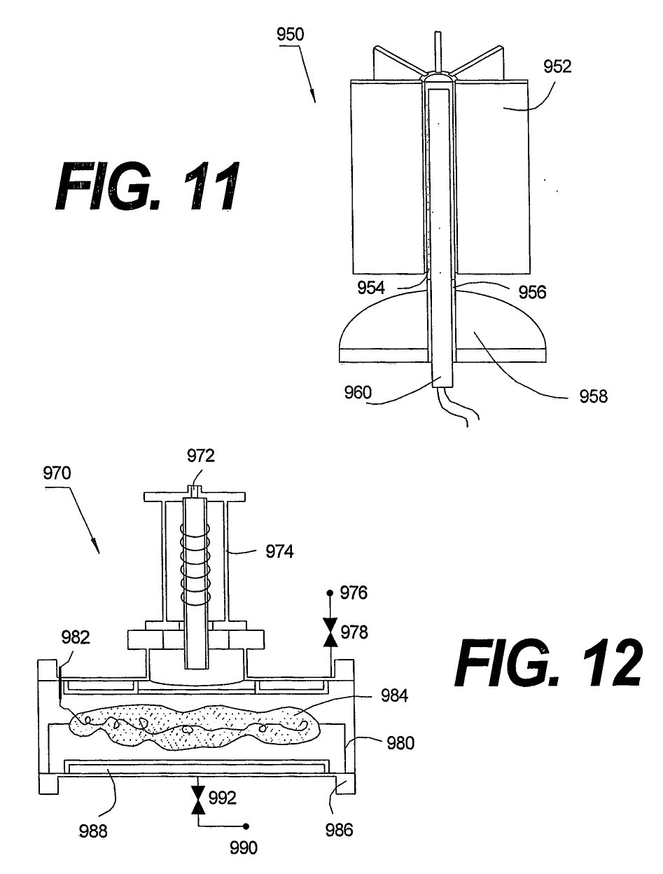

In yet another embodiment abatement element 950 is designed for quick replacement as depicted in FIG. 11. Element 950 provides a quick mounting vacuum flange 958 which is made from poorly thermally conducting material such as stainless steel. A sleeve which is partially made from poorly thermally conductive material (section 956) such as stainless steel and partially made from a good thermally conducting material (section 954) such as nickel 200 alloy, extends from flange 958. The end of section 954, and the seams between sections 954 and 956 and between 956 and flange 958 are vacuum sealed. A cartridge heater 960, commercially available from many manufacturers is inserted into the sleeve from the side that is outside the vacuum. High area element 952 made, for example, from porous molybdenum is mounted over section 954 with adequate thermal contact. Element 952 has high area and can be controlled at a desired temperature for effective abatement. Assembly 950 is designed for quick maintenance by removing an exhausted element and swapping it with a fresh element.

Finally, plasma generated by means of RF, Microwave etc. can be used to induce breakdown of reactive effluent components to deposit solid films inside the abatement chamber. For example, SiO₂ deposition from TEOS mixed with inert gas and/or oxygen. The byproducts of the abatement process, C₂H₄, C₂H₅OH and H₂O all are volatile and are easily hauled by the vacuum pump. For example, FIG. 12 depicts schematically an apparatus 970 where an abatement chamber is equipped with a remote plasma source 974 such as an helical resonator. Abatement gas is inserted through the source where high density plasma activates the gas. The plasma is carried further downstream and induces deposition over a high area element 984. For example, steel-wool can be used by carefully mounting a continuous body of steel-wool over a grounded support 980 and 982. Improved maintainability can be achieved if the walls of abatement chamber 970 are protected by inert gas flow as described in reference to FIG. 6. If the walls are protected, the deposition is carried predominantly over the steel-wool element and maintenance can be carried effectively and quickly.

In another example a n×(FRE/PCC)/PUMP FCD system is utilized to handle and abate AlCl₃ emission from Al etch-systems. Many downstream abatement solutions were suggested and implemented to handle this material but the problem continues to be a performance and cost bottleneck. In particular, AlCl₃ is notoriously damaging to turbomolecular pumps. Our invention implements additive H₂O, ozone, H₂O₂, NH₃, N₂H₂, phenylhydrazine and other chemical compounds that react vigorously and efficiently with AlCl₃ to deposit Al₂O₃ or AlN or both as solid coating on the abatement element while generating volatile species that can pass through the foreline system (especially the turbomolecular pump). One of these byproducts is HCl that is hazardous but can be abated efficiently and cost effectively at the outlet of the pump by available conventional scrubbers. Alternatively, HCl may be converted to CCl₄ and other chlorohydrocarbons by adding reactive hydrocarbons into the abatement PCC.

In another example WF₆ and SiH₄ that are used for W (tungsten) LPCVD can be abated thermally at 300-350° C. at mild efficiency. However, to improve efficiency, excess SiH₄ can be injected into the abatement PCC. Once the effluent is rid of WF₆, SiH₄ can pass through the (lower that 200° C. temperature) foreline and pump without solidifying. In another example WNₓ is CVD grown from WF₆ and NH₃. At low temperature the unreacted reactants can form a polymer like high viscosity fluid that is detrimental to vacuum pumps. The pump can be saved by an abatement PCC having SiH₄ injection to rid the effluent from WF₆ by inducing W film deposition at temperature from 300-350° C.

The practical implementation of FCD according to the current invention should be optimized to the applications and is best customized to the specific needs of the equipment and the specific restrictions of the facilities. As such, the FCD method and apparatus lend themselves to substantial flexibility allowing independent fast control of downstream pressure at the vicinity of the chamber, deposition free conduit to a remote location where a bulky abatement PCC can be located, multiple abatement PCCs or conduit PCCs arranged to achieve maximum performance and convenience. All these possible designs and modifications can be made by those who are skilled in the art and are included within the scope of this invention.

Porous materials are manufactured routinely in the process of molding parts from a variety of metals, alloys and ceramics. Molding conveniently involves organic resins that are carbonized at high temperatures and sometimes eliminated in oxidizing environment. Most of these manufacturing processes aim at a final high-density product and therefore the porous body is typically sintered at high temperatures or pressed at high pressures and at elevated temperatures. The process of obtaining a high-density part involves dimensional change but the technology is so well developed that precision parts can still be manufactured with minimum or no required final machining. For the purpose of manufacturing porous abatement inserts the molding process is pursued to the point of carbonizing the resin and therefore, precision parts such the honeycomb illustrated in FIG. 8 can be manufactured at low cost. After carbonization the hardness of the parts is relatively poor but mechanical strength of the molds is excellent (while most parts tend to develop hardness but also brittleness upon sintering or isostatic pressing). Thermal conductivity depends on the porosity and the pore size and spans the range from close to bulk values to very low values at very high porosity. Tailoring pore size is also a mature technology involving either sizing the powder particles or the particles of organic fillers.

One particular advantageous PCC design may provide the first FRE at the outlet of the process chamber. Since FREs can be made with low profile they can always be implemented on the process chamber outlet, with ease. Following the first FRE, the wall-protected conduit can be part of the PCC volume that serves only to transport process effluents away from the chamber. Abatement may be performed in that conduit with a tubular abatement element (described with reference to FIGS. 11 and 12) or at a larger size PCC downstream to the conduit. Improved maintenance cycle may be provided for the walls of the PCC by implementing the concept for wall protection in the design of the PCC, as well.

### D. Maintenance

An objective of this invention is to rid process effluents from potentially solidifying ingredients in a form of thin film coating over removable inserts. The advantage of this approach is that high quality solid films can be deposited up to several hundreds of microns of thickness without flaking. In addition, maintenance involves quick replacement of elements that are coated with neutral stable films eliminating safety hazards that involve handling of deposits that are toxic and partially reactive.

Conveniently, the abatement PCC can be isolated by large area valves (gate valves) and the insert can be pulled out within minutes by breaking one or two elastomer seals. Following the installation of fresh insert the abatement PCC is connected to the foreline by opening the downstream gate valve first to evacuate the PCC followed by opening the upstream gate valve. The maintenance may involve the replacement of FREs upstream (824) and downstream (828) to the abatement PCC (826) that are also isolated by the gate valves as illustrated in FIG. 9. In some instances cost effective disposable porous or other high-area elements that are used by the insert can be implemented. In this case rebuilding the insert involves disposing the porous element (that contains no hazardous waste) and mounting a fresh porous element. For example, the steel wool element illustrated in FIG. 12.

In other cases it is cost effective to use multiple usage porous elements such as porous graphite or tungsten bodies. In this case rebuild involves also a wet clean to etch away the film and expose the porous part area. For example, the SiC/graphite element 924 described in FIG. 10 can be etched in HF solutions to completely remove SiO₂ films that are formed by TEOS abatement.

Although removing accumulated abatement products is cost effective and fast, certain applications may apply in situ dry clean of the porous element. For example NF₃ or ClF₃ can be used for in situ etch and removal of Si and W compound as is commonly implemented for in situ chamber clean purposes.

### E. Other Embodiments

The main objective of the present invention is to provide a cost effective and maintainable downstream apparatus with capability to control pressure and handle solid depositing reactive effluent mixtures. However, some applications may implement only one or several of the elements that compose the system. For example FRE/PCC/PUMP can be implemented for improved downstream pressure control. PCCs may be used for the implementation of condensation traps or plasma chambers for PFCs conversion with the advantage of being able to sustain process in a forward flowing semi-isolated section of a vacuum foreline including introduction of additional reactants and including high temperature processes without any upstream or downstream adverse effects. Finally, the porous approach for inert gas wall protection can be universally implemented to protect walls of process chambers and vacuum lines from growing deposits or to eliminate sorption and condensation on walls in process chambers or pipelines.

The descriptions and examples of the preferred embodiment further explain the principles of the invention and are not meant to limit the scope of invention to any specific method or apparatus. All suitable modifications, implementations and equivalents are included in the scope of the invention as defined by the summary of the invention and the following claims:

1. A sub-atmospheric downstream pressure control apparatus (200), characterized by:
a first flow restricting element (FRE)(202);
a pressure control chamber (PCC) (204) located in serial fluidic communication downstream from said first FRE;
a second FRE (206) located in serial fluidic communication downstream from said PCC;
a gas source (208); and
a flow controlling device (210) in serial fluidic communication downstream from said gas source and upstream from said PCC.

2. A sub-atmospheric downstream pressure control apparatus as in claim 1 further characterized by:
a reactive gas source (422) connected in serial fluidic communication upstream from said PCC; and
an abatement element (420) located within said PCC.

3. A sub-atmospheric downstream pressure control apparatus as in claim 1 further characterized by:
a third FRE (504) connected in serial fluidic communication downstream from said PCC;
an abatement chamber (502) connected in serial fluidic communication downstream from said third FRE;
a reactive gas source (506) connected in serial fluidic communication upstream from said abatement chamber; and
an abatement element (520) disposed within said abatement chamber.

4. A sub-atmospheric downstream pressure control apparatus as in claim 1 wherein a process chamber (304) is located in serial fluidic communication upstream from said first FRE;
said process chamber and said PCC (308) are formed as compartments within a single process vessel (324); and
said first FRE (306) is formed within the partition between said process chamber and said PCC.

5. A wafer processing apparatus comprising a process chamber (10), said apparatus characterized by;
a process reactive gas supply line (12) from a process gas source in serial fluidic communication upstream from said process chamber;
an upstream flow control device located in serial fluidic communication upstream from said process chamber and downstream from said process gas source;
a first flow restricting element (202) located in serial fluidic communication downstream from said process chamber;
a pressure control chamber (PCC) (204) located in serial fluidic communication downstream from said first FRE;
a second FRE (206) located in serial fluidic communication downstream from said PCC;
a gas source (208); and
a flow controlling device (210) in serial fluidic communication downstream from said gas source and upstream from said PCC.

6. A sub-atmospheric downstream pressure control apparatus as in claim 5 further characterized by:
a reactive gas source (422) connected in serial fluidic communication upstream from said PCC; and
an abatement element (420) located within said PCC.

7. A sub-atmospheric downstream pressure control apparatus as in claim 5 further characterized by:
a third FRE (504) connected in serial fluidic communication downstream from said PCC (200);
an abatement chamber (500) connected in serial fluidic communication upstream from said third FRE;
a reactive gas source (506) connected in serial fluidic communication upstream from said abatement chamber; and
an abatement element (520) located within said abatement chamber.

8. A sub-atmospheric downstream pressure control apparatus as in claim 5 wherein a process chamber (304) is located in serial fluidic communication upstream from said first FRE (306);
said process chamber and said PCC (308) are formed as compartments within a single process vessel (324); and
said first FRE is formed within the partition between said process chamber and said PCC.

9. A sub-atmospheric downstream pressure control apparatus as in claim 5 wherein said process is LPCVD.

10. A sub-atmospheric downstream pressure control apparatus as in claim 5 wherein said process is RIE.

11. A sub-atmospheric downstream pressure control apparatus as in claim 5 wherein said process is PECVD.

12. A downstream pressure control method, comprising controlling a flow of process gas into a process chamber; said method characterized by:
providing a flow of gas into a pressure control chamber (PCC) connected in serial fluidic communication downstream from said process chamber;
controlling fluid flow with a first flow restricting element (FRE) located in serial fluidic communication downstream from said process chamber and upstream from said PCC; and
controlling the pressure at said process chamber by adjusting the pressure in said PCC to impact the pressure gradient over said first flow restricting element.

13. A method for sub-atmospheric reactive gas abatement, characterized by:
providing a substantial pressure gradient at an inlet to an abatement space;
providing a substantial pressure gradient at an outlet from said abatement space;
flowing a reactive abatement gas into said abatement space;
reacting with process gas exhaust effluents to produce substantially stable and inert solid; and
substantially localizing said substantially stable and inert solid within said abatement chamber.

14. A method for sub-atmospheric reactive gas abatement of process gas exhaust effluent, said method characterized by:
providing a substantial pressure gradient at an inlet to an abatement space;
providing a substantial pressure gradient at an outlet from said abatement space;
flowing a reactive abatement gas into said abatement space;
reacting said reactive abatement gas with said process gas exhaust effluent to produce a substantially volatile effluent gas; and
transporting said substantially volatile effluent gas through a pump foreline and pump substantially without further reaction and substantially without growth of film deposits.

15. A wall-protected process chamber (710, 730), comprising:
an external enclosure (602);
a gas permeable internal enclosure (604) disposed within said external metallic enclosure and enclosing said process chamber;
a seal (608, 610) between said internal enclosure and said external metallic enclosure, said internal enclosure and said external enclosure defining a substantially sealed space (606) between the outer wall of said internal enclosure and the inner wall of said external metallic enclosure; and
a source (612) of a pressurized inert gas in fluid communication with said sealed space; whereby said pressurized inert gas flows through said gas permeable internal enclosure to protect said process chamber wall.
